(19) United States
(12) Patent Application Publication
(10) Pub. No.: US 2010/0207645 A1
(43) Pub. Date: Aug. 19, 2010

(54) SENSOR DEVICE FOR DETECTING AT LEAST ONE OBJECT IN A SWIVEL REGION OF A CONVERTIBLE TOP AND CORRESPONDING INSTALLATION METHOD

(75) Inventor: Rudolf Dietl, Munich (DE)

Correspondence Address: FITCH, EVEN, TABIN & FLANNERY, P. O. BOX 18415, WASHINGTON, DC, 20036, US

(73) Assignee: WEBASTO AG, Stockdorf (DE)

(21) Appl. No.: 12/667,809

(22) PCT Filed: Jun. 24, 2008
(86) PCT No.: PCT/DE08/01012

§ 371 Date: Mar. 30, 2010

(30) Foreign Application Priority Data
Jul. 20, 2007 (DE) 10 2007 034 001.1

(51) Int. Cl. G01R 27/26

(52) U.S. Cl. 324/663

(57) ABSTRACT

The invention relates to a sensor device, in particular for detecting at least one object in a swivel region of a convertible top, comprising at least one sensor which is formed at least partly by a convertible top rod system. According to the invention, the sensor further comprises a conductor path structure connected in an electrically conductive manner to the convertible top rod system so as to form a sensor electrode. The invention further relates to a method for installing such a sensor device. Furthermore, the invention relates to a conductor path structure, in particular a flexible and substantially flat conductor path structure. According to the invention, said structure can be attached to a convertible top rod system, in particular to one or more links of a link system of the convertible top rod system, wherein the conductor path structure can be connected to the convertible top rod system in an electrically conductive manner via one or more contact regions.

The invention relates to a sensor device, in particular for detecting at least one object in a swivel region of a convertible top, comprising at least one sensor which is formed at least partly by a convertible top rod system.

The invention further relates to a method for installing a sensor device which serves in particular for detecting at least one object in a swivel region of a convertible top, comprising at least one sensor which is formed at least partly by a convertible top rod system.

The invention further relates to a conductor path structure, in particular a conductor path structure which is flexible and formed substantially flat.

A generic sensor device is known from DE 10 2006 004 278 A1, for example. This prior art document describes a sensor device for detecting an object or an object in a swivel region of a convertible top, the sensor device comprising a sensor which can detect the characteristics of a field associated with the convertible top. This sensor device further comprises an evaluating device for evaluating the field characteristics detected by the sensor. For example, the convertible top, or one or more sections thereof, serves as a field source. The convertible top, or one or more sections thereof, can thus be formed as an electrode of the sensor. A further electrode of the sensor is then provided in this case by, for example, a vehicle body put on mass. Thus the electrode formed by the convertible top and the electrode put on mass formed by the vehicle body do at least partly form the sensor, the detected signals of which are evaluated by the evaluating device for detecting the object situated between the convertible top and the vehicle body. In order to form the convertible top as the electrode of the sensor, several possibilities are suggested in DE 10 2006 004 278 A1. On the one hand, a convertible top rod system of the convertible top, which is formed at least by a plurality of links of a link system rotatably coupled to each other, can be used at least partly as an electrode. To this end, the individual links are coupled to each other via electrically conductive bearings or joints. Such conductive bearings may be realized in particular at least partly by electrically conductive sockets. However, the conductivity of these sockets may be negatively affected by changing or varying ambient conditions which are caused for example by a variable climate, so that the conductivity of these sockets deteriorates. In the worst case these sockets may be affected such that they completely lose their electric conductivity so that only the links connected to each other in an electrically conductive manner still form the electrode. This may lead to the sensor detecting falsified field characteristics or being no more operational.

According to the prior art, in order not to be necessarily dependent on the conductivity of the bearing of the convertible top rod system, cable trees are retrofitted on the left side or on both sides within the convertible top rod system and clipped with the individual links, screwed, or joined by cable binders, wherein one or more cables of the cable tree may serve as an electrode. This measure represents a considerable cost factor and requires an adequate construction space required for mounting the cable tree. In particular, according to this solution, attention also needs to be paid to the cable trees not being kinked or bent over their required minimum bending radius during the pivoting of the convertible top.

DE 10 2006 004 278 A1 further suggests, instead of forming the convertible top rod system as an electrode, providing a cover tarpaulin having electrical conductor paths and covering the convertible top rod system, the electrical conductor paths forming essentially a fish bone pattern. Thereby, the convertible top cover tarpaulin of the convertible top acts as a field source and thus forms an electrode of the sensor. However, such an implementation of the convertible top tarpaulin is extremely elaborate and costly.

It is therefore an object of the invention to further develop the generic sensor devices and methods for installing such sensor devices and the conductor paths such that the above mentioned disadvantages may be overcome at least partly and in particular the required construction space and costs may be reduced.

This object is achieved by the features of the independent claims.

Advantageous embodiments of the invention are set forth in the dependent claims.

The sensor device according to the invention is distinguished from the generic prior art in that the sensor further comprises a conductor path structure which is connected to the convertible top rod system in an electrically conductive manner so as to form a sensor electrode. The conductor path structure is preferably formed as a flat conductor or flexible substantially flat conductor plate individually manufactured for the convertible top rod system, in particular for a link system comprising a plurality of links. The conductor path structure may likewise be formed partly as a flexible printed conductor plate which comprises one or more printed two-dimensional conductor paths and which may optionally further comprise non-two-dimensional conductors which are fixed to the flexible conductor plate in a manner known to the person skilled in the art. In order to establish the electrically conductive connection between the conductor path structure and the convertible top rod system, preferably at least one conductor path of the conductor path structure is contacted through to the convertible top rod system.

The sensor device according to the invention may advantageously further be characterized in that the conductor path structure, or one or more sections thereof, is positioned adjacent to the convertible top rod system or alongside the convertible top rod system. Thus the conductor path structure is positioned and attached alongside and preferably directly adjoining links of a link system of the convertible top rod system. In order to attach the conductor path structure to the individual links, ears or 90-degrees-retractions may be provided, for example, via which in addition to the attachment, also the electrically conductive connection may be established by contacting through to the convertible top rod system. These ears or 90-degrees-retractions for fixing the conductor path structure comprise, for example, transverse nails, rivets, pins, screws, which are introduced into corresponding bores at the respective links. Solder joints or spot weldings may of course also serve to attach the conductor path structure.

In addition, the sensor device according to the invention may be implemented such that the conductor path structure is formed flexible and substantially flat and/or is attached to the convertible top rod system. In particular with the conductor path structure attached to a plurality of links of the link arrangement, an extremely flexible conductor path structure is advantageous, since very small bending radii of the conductor path structure may occur, for example, when the convertible top rod system is collapsed.

Furthermore, the sensor device according to the invention may be realized such that the convertible top rod system comprises a link system comprising a plurality of links which are rotatably coupled to each other and which are selectively coupled to each other in an electrically conductive manner via their couplings or isolated against each other. The couplings or bearings of adjacent links are preferably implemented at least partly as bearing sockets. For example, electrically conductive bearing sockets are thus used to establish an electrically conductive connection between adjacent links. Likewise, selected links can be purposely isolated from the remaining links of the link system and hence do not act as an electrode of the sensor. For example, in this case isolated bearings are used, which can be realized at least partly by electrically isolating plastic sockets.

Furthermore, the sensor device according to the invention can be realized such that the coupling of different links is formed such that it establishes an electrically conductive connection between the links or acts to isolate electrically, depending on the mutual orientation of the different links. Such an implementation of the coupling and the bearing of adjacent links, respectively, is advantageous primarily if a selected link is to be exempted from the sensor only after undergoing a predetermined pivot motion which corresponds merely to a portion of the complete pivot motion of the convertible top. Thus this link at first acts as at least one section of the electrode of the sensor but is electrically decoupled from the electrode of the sensor after performing its predetermined pivot motion.

The sensor device may furthermore be formed such that the sensor is a capacitive sensor. In this case, the links of the link system of the convertible cover rod system form an electrode of a capacitive sensor, for example.

The sensor device according to the invention may further be formed such that at least one conductor path of the conductor path structure is coupled to the convertible top rod system or to the links in an electrically conductive manner, wherein the conductor path is coupled at one or more sections to one or more links in an electrically conductive manner. The electrically conductive connection of adjacent links which are coupled together may be interrupted, for example directly at their coupling, due to constantly changing ambient conditions. The conductor path structure being electrically coupled respectively to a plurality of links and in particular to adjacent links, a redundancy is produced in a reliable manner, so that an interruption of the electric connection at the coupling of the links does at least not entail a failure of the sensor. In particular, the sections which serve to establish the electrically conductive connection between the conductor path structure and the respective links may be provided for fixing the conductor path structure to the links.

Preferably, the sensor device according to the invention is implemented such that the conductor path structure comprises one or more further conductor paths which are provided at least for supplying current, for transferring data, or as a mass conductor. Thereby the functionality of a cable tree can be achieved by the conductor path structure, yet without being affected by the above mentioned disadvantages of using a cable tree.

The sensor device according to the invention may furthermore be implemented such that the conductor path structure is formed such that components (SMD) which are surface-mountable by surface-mount technique (SMT), in particular surface-mountable electronic components, can be coupled to the conductor path structure. Likewise further electronic components such as further sensor elements can be integrated directly into the layout of the conductor path structure in an advantageous manner. This can be achieved in particular by SMD (surface-mounted device) technique.

The sensor device according to the invention may furthermore be formed advantageously such that the conductor path structure is formed with one or more attachment sections for being attached to the convertible top rod system or to the link system via which the electrically conductive connection is established.

The sensor device according to the invention is further distinguished in that one or more sensors are integrated by surface-mount technique (SMD) at least partly in the conductor path, which further sensors operate in particular on the basis of electromagnetic waves, in particular microwaves, or sound, in particular ultrasound. As the surface-mount technique (SMD) permits integrating further sensors in the conductor path structure, detection of an object in the swivel region of the convertible top may be rendered even more reliable. Thereby several sensors operating on the basis of different operating principles may be realized using the conductor path structure.

The sensor device according to the invention may furthermore be realized such that the electrically conductive connection between the convertible top rod system and the conductor path structure can be manufactured by a melting method, in particular a metal melting method. For example, the electrically conductive connection can be produced by spot welding or soldering.

In a preferred embodiment, the sensor device according to the invention is realized such that the conductor path structure is formed as a 2D or as a 3D conductor path structure.

The method according to the invention is distinguished from the generic prior art in that the sensor comprises a conductor path structure which is connected to the convertible top rod system in an electrically conductive manner so as to form a sensor electrode. Thus, the advantages mentioned in the context of the sensor device according to the invention are obtained in the same or similar manner. In order to avoid repetitions, reference is therefore made to the explanations relating to the sensor device according to the invention.

The same applies analogously for the following preferred embodiments of the method according to the invention. In order to avoid repetitions, reference is therefore made to the corresponding explanations regarding the sensor device according to the invention.

The method according to the invention may be advantageously further characterized in that the conductor path structure, or one or more sections thereof, is arranged adjacent to the convertible top rod system or alongside the convertible top rod system.

Furthermore, the method according to the invention can be implemented such that the conductor path structure is formed flexible and substantially flat and/or is attached to the convertible top rod system.

Furthermore, the method according to the invention can be realized such that the convertible top rod system comprises a link system comprising a plurality of links coupled rotatably to each other and which are selectively connected to each other in an electrically conductive manner via their couplings or are isolated against each other.

Furthermore, the method according to the invention can be realized such that the coupling of different links establishes an electrically conductive connection between the links or electrically isolates the links against each other, depending on the mutual orientation of the different links.

Preferably, the method according to the invention is performed such that the sensor is formed as a capacitive sensor.

The method according to the invention can further be realized such that at least one conductor path of the conductor path structure is connected to the convertible top rod system or to the links in an electrically conductive manner, wherein the conductor path is connected at one or more sections to one and/or more than one links in an electrically conductive manner.

The method according to the invention can further be realized such that the conductor path structure comprises one or more further conductor paths which are provided at least for current supply, for data transfer, or as a mass conductor.

Furthermore, the method according to the invention can be realized such that the conductor path structure is formed such that components (SMD) which are surface-mountable by surface-mount technique (SMT), in particular surface-mountable electronic components, can be coupled to the conductor path structure.

In addition, the method according to the invention can be realized such that the conductor path structure is formed with one or more attachment sections for being attached to the convertible top rod system or to the link system via which the electrically conductive connection is established.

The method according to the invention may be further distinguished in that one or more further sensors are integrated in the conductor path structure by surface-mount technique (SMD) at least partially, which further sensors operate in particular on the basis of electromagnetic waves, in particular microwaves or sound, in particular ultrasound.

Furthermore, the method according to the invention can be implemented such that the electrically conductive connection between the convertible top rod system and the conductor path structure is produced via a melting method, in particular a metal melting method.

The method according to the invention is preferably implemented such that the conductor path structure is formed as a 2D or 3D conductor path structure.

The conductor path structure according to the invention is distinguished from the generic prior art in that it can be attached to a convertible top rod system, in particular to one or more links of a link system of the convertible top rod system, wherein the conductor path structure can be connected to the convertible top rod system in an electrically conductive manner via one or more contact regions. Also in this case the advantages which were explained above in the context of the sensor device according to the invention are obtained in the same or similar manner. In order to avoid repetitions, reference is therefore made to the corresponding explanations concerning the sensor device according to the invention.

The same applies analogously for the following preferred embodiment of the conductor path structure according to the invention. In order to avoid repetitions, reference is therefore made again to the corresponding explanations regarding the sensor device according to the invention.

The conductor path structure according to the invention may be advantageously formed such that the contact regions at the same time serve as attachment regions at the convertible top rod system.

Preferred embodiments of the invention are subsequently explained by way of example, with reference to the figures.

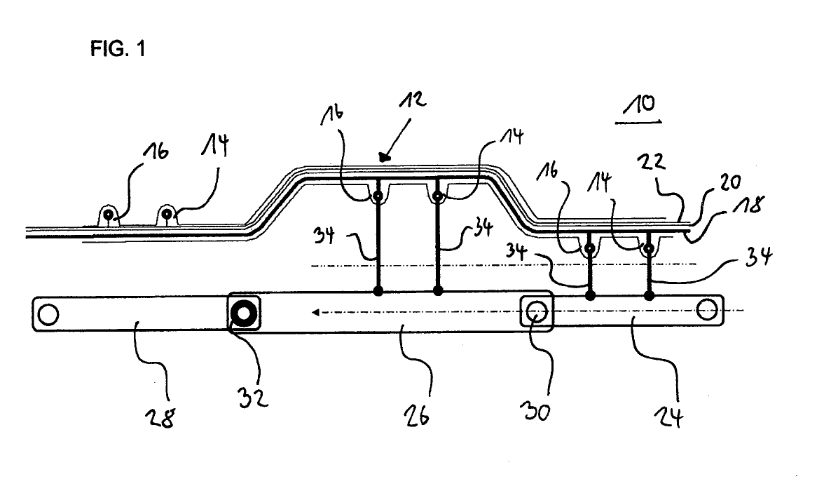

FIG. 1 shows a schematic representation of the sensor device according to the invention according to a first exemplary embodiment of the invention, which is suitable for performing the method according to the invention.

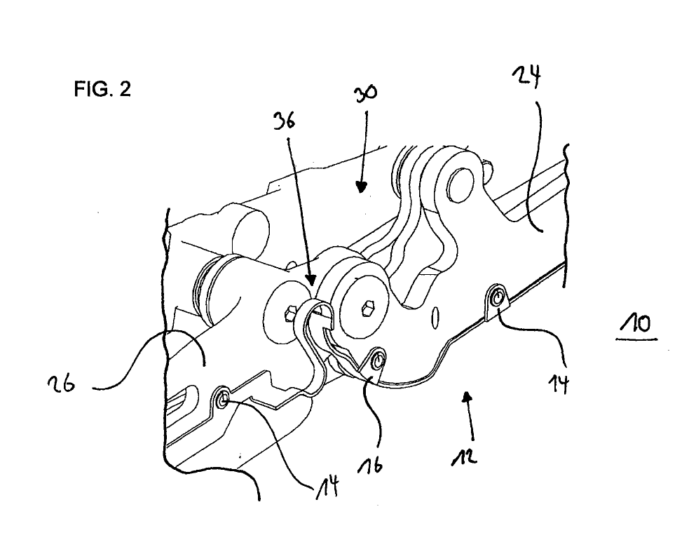

FIG. 2 shows a spatial representation of the sensor device according to the invention of FIG. 1, wherein the convertible top rod system is arranged in a first position.

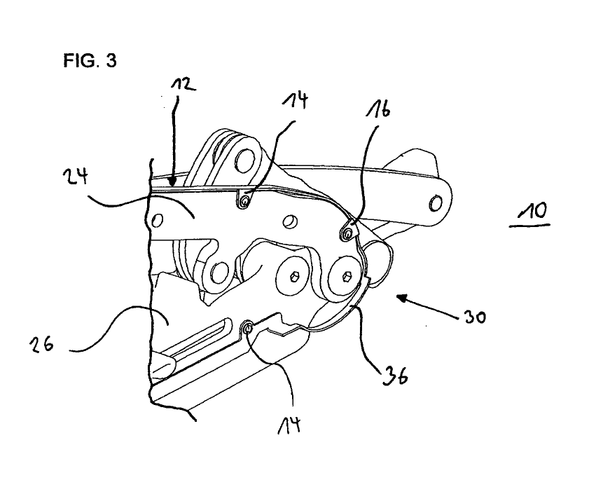

FIG. 3 is a spatial representation of the sensor device according to the invention of FIG. 1, wherein the convertible top rod system is arranged in a second position.

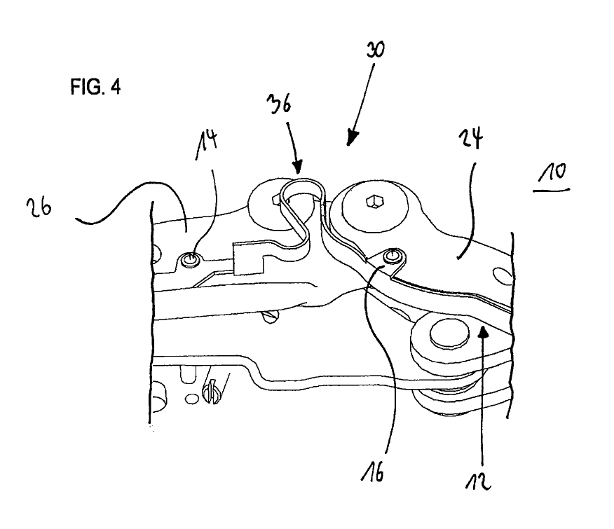

FIG. 4 is a further spatial representation of the sensor device according to the invention of FIG. 1, wherein the convertible top rod system is arranged in the first position.

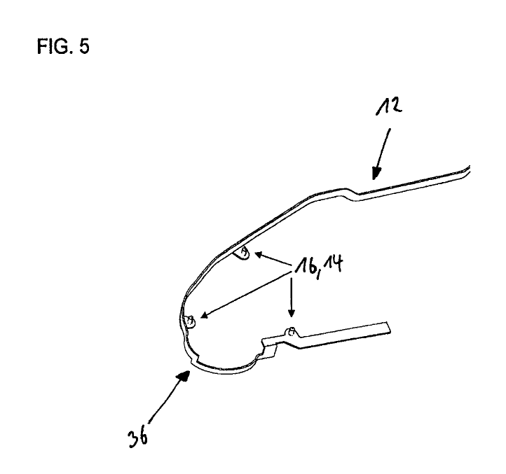

FIG. 5 is a spatial representation of the conductor path structure according to the invention.

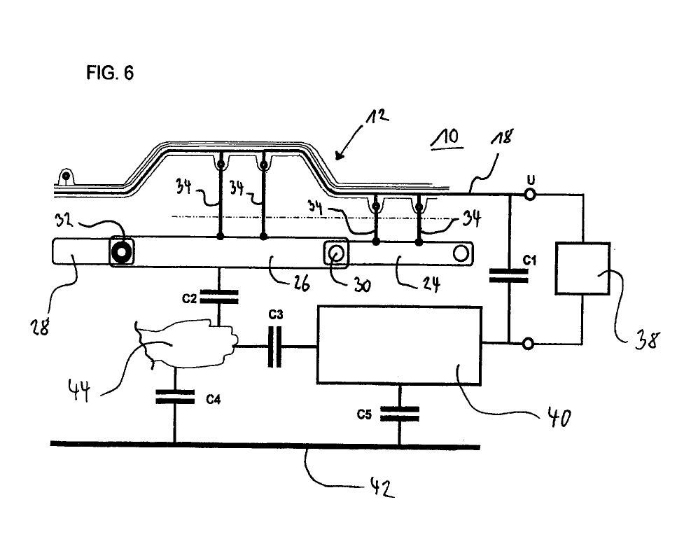

FIG. 6 is a schematic representation of the sensor device according to the invention of FIG. 1, with an object situated in the swivel region of the convertible top rod system.

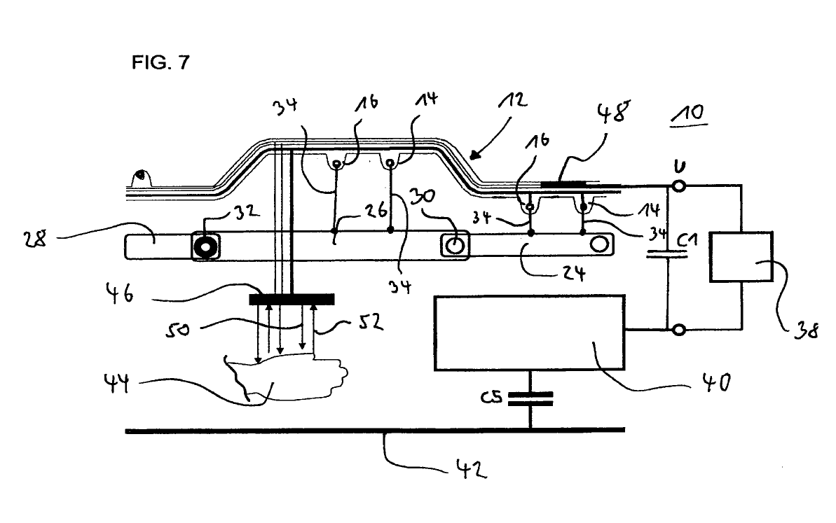

FIG. 7 is a schematic representation or the sensor device according to a second exemplary embodiment of the invention, which is suitable for performing the method according to the invention.

FIG. 1 shows a schematic representation of the sensor device 10 according to a first exemplary embodiment of the invention which is suitable for performing the method according to the invention. The sensor device 10 serves to detect at least one object in a swivel region in a convertible top and for this purpose comprises at least one sensor. In this exemplary embodiment the sensor is formed at least partly by a convertible top rod system connected to a flexible conductor path structure 12, which is formed substantially flat, in particular a flexible and flat conductor plate comprising a plurality of conductor paths, in an electrically conductive manner. The convertible top rod system comprises a link system comprising a plurality of links 24, 26, 28, wherein respectively adjacent links are rotatably coupled to each other. In the case shown, there are represented, by way of example, only three links 24, 26 and 28; the number of links however depends on the implementation of the convertible top or the convertible top rod system, respectively, which may comprise more than three links. The link 24 is rotatably coupled to the adjacent link 26 via an electrically conductive bearing 30 which is formed in particular by an electrically conductive bearing socket. The link 26 is rotatably coupled to the adjacent link 28 via an electrically isolating bearing 32 which is formed in particular as an electrically isolating plastic socket. In this case, the electrically conductive bearing 30 provides a permanent electrically conductive connection between the links 24 and 26 irrespective of the orientation of the links 24 and 26 relative to each other. Likewise, the electrically isolating bearing 32 permanently isolates the links 26 and 28 against each other.

In an alternative embodiment the bearings 30 and 32 may however be designed such that they establish an electrically conductive connection or provide an electric isolation, depending on the mutual orientation of the corresponding links 24 and 26 as well as 26 and 28.

In order to form the convertible top rod system, in particular the rod system comprising the links 24 and 26, as a sensor electrode of the sensor, the conductor path structure 12 is connected to the links 24 and 26 in an electrically conductive manner or is contacted through to the links 24 and 26. In particular, the conductor path structure 12 in this exemplary embodiment comprises, by way of example, three conductor paths 18, 20 and 22, wherein the conductor path 18 is connected to the links 24 and 26 via contact regions 14, 16 by means of via contacts 34 in an electrically conductive manner. In the case shown, the links 24 and 26 thus act as a sensor electrode of the sensor, whereas the link 28 is isolated from the links 24, 26 and in this case does not comprise a function related to the sensor.

FIG. 2 shows a spatial representation of the sensor device 10 according to the invention of FIG. 1, wherein the convertible top rod system with its links 24 and 26 is arranged in a first position. For example, the convertible top in the first position may be in a closing position which completely covers or upwardly closes a vehicle occupant space of a vehicle. As may be seen from FIG. 2, the conductor path structure 12 extends along the links 24 and 26 and is adjoining or adjacent thereto. To establish the electrically conductive connection, the conductor path structure 12 is coupled to, for example, the link 24 via the contact regions 14 and 16, wherein the via contacting of the conductor path 18 to the link 24 is effected via the contact regions 14 and 16. The contact regions 14 and 16 of the conductor path structure 12 at the same time serve to fix or attach the conductor path structure 12 directly to the links 24 and 26. As can be seen in particular from FIG. 2, the conductor path structure 12 comprises close to the bearing 30 a strip-like extremely flexible and bendable conductor path section 36 which is strongly bent due to the arrangement or orientation of the links 24 and 26 in the first position. In particular, the conductor path section 36 is formed as a two-dimensional loop, whereby the electrically conductive connection to the respectively next fixing or coupling of adjacent links is assured. Preferably, all conductor path sections which are adjacent to bearings may be formed more flexible than other conductor path sections of the conductor path structure which are not adjacent to bearings.

FIG. 3 shows a spatial representation of the sensor device 10 according to the invention of FIG. 1, wherein the convertible top rod system with the links 24 and 26 is arranged in a second position. In this case, the convertible top is in an opened position, for example, so that the vehicle occupant's space of the vehicle is exposed at least upwardly. As can be seen in particular from FIG. 3, the flexible conductor path section 36 is less compressed or bent in the second position, that is, its bending radius is greater as compared to the first position.

FIG. 4 shows a further spatial representation of the sensor device 10 according to the invention of FIG. 1, wherein the convertible top rod system is represented in the first position. In this case the flexible conductor path section 36 again has a smaller bending radius as compared to the second position.

FIG. 5 shows a spatial representation of the conductor path structure 12 according to the invention, wherein in the case shown, the conductor path structure 12 according to the invention is not attached to the links 24 and 26. In particular, FIG. 5 shows the contact regions 14, 16 of the conductor path structure 12 according to the invention, via which the conductor path structure 12 can be attached to the links 24, 26 of the link system of the convertible top rod system and via which the electrically conductive connection to the links 24, 26 may likewise be established.

FIG. 6 shows a schematic representation of the sensor device 10 according to the invention of FIG. 1, with an object 44 situated in the swivel region of the convertible top. Furthermore, the sensor device 10, in particular the conductor path structure 12 with its conductor path 18, is coupled to an evaluating device 38. The evaluating device 38 is further coupled to a vehicle body 40 of the vehicle, wherein the vehicle body is isolated from the convertible top rod system. The convertible top rod system 24, 26 thus forms a sensor electrode, whereas the vehicle body 40 forms the other sensor electrode of the sensor which is put on mass. Due to this arrangement, there is a plurality of capacities C1 to C5. The vehicle body 40 is electrically isolated from the sensor device 10, so that there is a capacity C1 between the sensor device 10 and the vehicle body 40. The vehicle body 40 is furthermore electrically isolated against a road surface 42 acting as mass or grounding, so that furthermore a capacity C5 is present between the vehicle body 40 and the road surface 42. Furthermore, FIG. 6 shows the object 44 which in particular represents a hand of a person, for example of a driver of the vehicle. Because of the object 44, there may be a plurality of capacities; in particular, there is a capacity C4 between the object 44 and the road surface 42, a capacity C3 between the object 44 and the vehicle body 40 and a capacity C2 between the convertible top rod system 24, 26 acting as a sensor electrode and the object 44.

In this exemplary embodiment, during operation of the sensor device 10 according to the invention, the capacity C1 which is present between the vehicle body 40 and the convertible top rod system, in particular the links 24 and 26 of the link system, is detected. For example, a characteristic capacity behaviour of a complete pivot motion of the convertible top, in particular the convertible top rod system, with no object situated in the swivel region, may thus be pre-stored in the evaluating device 48. If the object 44 is in the swivel region of the convertible top, the evaluating device can detect or capture changes or deviations with respect to the characteristic capacity behaviour between the electrodes using the sensor device 10, in particular the two electrodes, so that in this case a blocking protection control is performed by the evaluating device 38 or a control device associated with the evaluating device 38. The blocking protection may, for example, cause the pivot motion of the convertible top to stop or likewise perform a reversal of the pivot motion. The deviations from the characteristic capacity behaviour of the capacity C1 may in particular be detected by the object 44 contacting the convertible top rod system. Likewise it is also possible to detect the deviations from the characteristic capacity behaviour of the capacity C1 when the object is merely situated between the convertible top rod system and the vehicle body without however touching them.

FIG. 7 shows a schematic representation of the sensor device 10 according to a second exemplary embodiment of the invention which is suitable for performing the method according to the invention. In order to avoid repetitions, the description of this exemplary embodiment merely addresses the differences with respect to the first exemplary embodiment. Identical or similar components are therefore designated using the same reference symbols. In addition to the via contacting of the conductor path 12 to the convertible top rod system 24, 26 in FIG. 7, the conductor path structure 12 comprises transmit/receive devices 46 and 48 integrated in the conductor path structure as SMD components (surface-mountable components/structural elements). These transmit/receive devices 46 and 48 operate, for example, on the basis of ultrasound or on the basis of electromagnetic waves such as microwaves. All swivel regions of the convertible top can be monitored on the basis of such SMD components 46, 48 integrated in the conductor path structure 12. Thus, the transmit/receive device 46 emits e.g. microwaves 50 which are partially absorbed and reflected in the form of reflected microwaves 52 by the object 44 situated in the swivel region of the convertible top. These reflected microwaves 52 are in turn received by the transmit/receive device 46 wherein the evaluating device 32 can detect an object in the swivel region of the convertible top on the basis of the intensity or delay of the reflected microwaves 52, for example. In particular, the distance and the position of the object 44 can be detected by the transmit/receive device 46 via the evaluating device 38.

The features of the invention disclosed in the above description, in the drawings and in the claims may be essential to realizing the invention either individually or in any combination.

### LIST OF REFERENCE SYMBOLS

10 sensor device
12 conductor path structure
14 contact region
16 contact region
18 conductor path
20 conductor path
22 conductor path
24 link
26 link
28 link
30 electrically conductive bearing
32 electrically isolated bearing
34 via contact
36 flexible conductor path section
38 evaluating device
40 vehicle body
42 road surface or mass
44 object
46 transmit/receive device
48 transmit/receive device
50 emitted electromagnetic wave
52 reflected electromagnetic wave
C1 capacitance
C2 capacitance
C3 capacitance
C4 capacitance
C5 capacitance

1. A sensor device, in particular for detecting at least one object in a swivel region of a convertible top, comprising at least one sensor which is formed at least partly by a convertible top rod system, characterized in that the sensor further comprises a conductor path structure connected in an electrically conductive manner to the convertible top rod system so as to form a sensor electrode.

2. The sensor device of claim 1, characterized in that the conductor path structure, or one or more sections thereof, is arranged adjacent to the convertible top rod system or alongside the convertible top rod system.

3. The sensor device of claim 1, characterized in that the conductor path structure is flexible and substantially flat and/or is attached to the convertible top rod system.

4. The sensor device of claim 1, characterized in that the convertible top rod system comprises a link system comprising a plurality of links coupled rotatably to each other and which are selectively connected to each other in an electrically conductive manner via their couplings or isolated against each other.

5. The sensor device of claim 4, characterized in that the coupling of different links is formed so as to establish an electrically conductive connection between the links or provides an electrical isolation, depending on the mutual orientation of the different links.

6. The sensor device of claim 1, characterized in that the sensor is a capacitive sensor.

7. The sensor device of claim 1, characterized in that at least one conductor path of the conductor path structure is connected to the convertible top rod system or to the links in an electrically conductive manner, wherein the conductor path is connected at one or more sections to one and/or more links in an electrically conductive manner.

8. The sensor device of claim 1, characterized in that the conductor path structure comprises one or more further conductor paths provided at least for current supply, for data transfer, or as a mass conductor.

9. The sensor device of claim 1, characterized in that the conductor path structure is formed such that components (SMD) which are surface-mountable by surface-mount technique (SMT), in particular surface-mountable electronic components, can be coupled to the conductor path structure.

10. The sensor device of claim 1, characterized in that the conductor path structure is formed with one or more attachment sections for being attached to the convertible top rod system or to the link system via which the electrically conductive connection is established.

11. The sensor device of claim 1, characterized in that one or more further sensors are integrated in the conductor path structure by surface-mount technique (SMD) at least partially, which further sensors operate in particular on the basis of electromagnetic waves, in particular microwaves or sound, in particular ultrasound.

12. The sensor device of claim 1, characterized in that the electrically conductive connection between the convertible top rod system and the conductor path structure can be produced by a melting method, in particular a metal melting method.

13. The sensor device of claim 1, characterized in that the conductor path structure is formed as a 2D or as a 3D conductor path structure.

14. A method for installing a sensor device which serves in particular for detecting at least one object in a swivel region of a convertible top and comprises at least one sensor formed at least partly by a convertible top rod system, characterized in that the sensor further comprises a conductor path structure which is connected to the convertible top rod system in an electrically conductive manner so as to form a sensor electrode.

15. The method of claim 14, characterized in that the conductor path structure, or one or more sections thereof, is arranged adjacent to the convertible top rod system or alongside the convertible top rod system.

16. The method of claim 14, characterized in that the conductor path structure is formed flexible and substantially flat and/or is attached to the convertible top rod system.

17. The method of claim 14, characterized in that the convertible top rod system comprises a link system comprising a plurality of links coupled rotatably to each other and which are selectively connected to each other in an electrically conductive manner via their couplings or are isolated against each other.

18. The method of claim 17, characterized in that the coupling of different links establishes an electrically conductive connection between the links or electrically isolates the links against each other, depending on the mutual orientation of the different links.

19. The method of claim 14, characterized in that the sensor is formed as a capacitive sensor.

20. The method of claim 14, characterized in that at least one conductor path of the conductor path structure is connected to the convertible top rod system or to the links in an electrically conductive manner, wherein the conductor path is connected at one or more sections to one and/or more than one links in an electrically conductive manner.

21. The method of claim 14, characterized in that the conductor path structure comprises one or more further conductor paths which are provided at least for current supply, for data transfer, or as a mass conductor.

22. The method of claim 14, characterized in that the conductor path structure is formed such that components (SMD) which are surface-mountable by surface-mount technique (SMT), in particular surface-mountable electronic components, can be coupled to the conductor path structure.

23. The method of claim 14, characterized in that the conductor path structure is formed with one or more attachment sections for being attached to the convertible top rod system or to the links system via which the electrically conductive connection is established.

24. The method of claim 14, characterized in that one or more further sensors are integrated in the conductor path structure by surface-mount technique (SMD) at least partially, which further sensors operate in particular on the basis of electromagnetic waves, in particular microwaves or sound, in particular ultrasound.

25. The method of claim 14, characterized in that the electrically conductive connection between the convertible top rod system and the conductor path structure is produced via a melting method, in particular a metal melting method.

26. The method of claim 14, characterized in that the conductor path structure is formed as a 2D or 3D conductor path structure.

27. A conductor path structure, in particular a flexible and substantially flat conductor path structure, characterized in that it can be attached to a convertible top rod system, in particular to one or more links of a link system of the convertible top rod system, wherein the conductor path structure can be connected to the convertible top rod system in an electrically conductive manner via one or more contact regions.

28. The conductor path structure of claim 27, characterized in that the contact regions at the same time serve as attachment regions at the convertible top rod system.
